(19) United States
(12) Patent Application Publication
(10) Pub. No.: US 2025/0105174 A1
(43) Pub. Date: Mar. 27, 2025

(54) SEMICONDUCTOR DEVICES AND METHODS OF MANUFACTURE

(71) Applicant: Taiwan Semiconductor Manufacturing Co., Ltd., Hsinchu (TW)

(72) Inventors: Chen Hua Huang, Taoyuan (TW); Cheng-Hsien Hsieh, Kaohsiung City (TW); Li-Han Hsu, Hsinchu (TW)

(21) Appl. No.: 18/416,410

(22) Filed: Jan. 18, 2024

Related U.S. Application Data
(60) Provisional application No. 63/584,543, filed on Sep. 22, 2023.

(51) Int. Cl. H01L 23/58; H01L 21/768; H01L 23/00; H01L 23/31; H01L 23/48

(52) U.S. Cl. CPC H01L 23/585; H01L 21/76898; H01L 23/3192; H01L 23/481; H01L 23/562; H01L 24/05; H01L 2224/05554; H01L 2924/35121

(57) ABSTRACT

A semiconductor device and method of manufacture are provided wherein semiconductor devices are attached over a semiconductor substrate. A seal ring within the semiconductor device is extended to include a first bond metal within a bonding layer and bonded to a second bond metal over the semiconductor substrate. Such a seal ring provided a more complete protection from cracking and delamination.

### PRIORITY CLAIM

This application claims the benefit of and priority to U.S. Provisional Patent Application No. 63/584,543, filed on Sep. 22, 2023, entitled “Semiconductor Structure with Bonding Seal Ring,” which application is incorporated herein by reference in its entirety.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20 nm node), which allows more components to be integrated into a given area. As the demand for miniaturization, higher speed and greater bandwidth, as well as lower power consumption and latency has grown recently, there has grown a need for smaller and more creative packaging techniques of semiconductor dies.

As semiconductor technologies further advance, stacked and bonded semiconductor devices have emerged as an effective alternative to further reduce the physical size of a semiconductor device. In a stacked semiconductor device, active circuits such as logic, memory, processor circuits and the like are fabricated at least partially on separate substrates and then physically and electrically bonded together in order to form a functional device. Such bonding processes utilize sophisticated techniques, and improvements are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a semiconductor wafer, in accordance with some embodiments.

FIGS. 2A-2B illustrate a semiconductor die with a seal ring, in accordance with some embodiments.

FIG. 3 illustrates a bonding of the semiconductor die to the semiconductor wafer, in accordance with some embodiments.

FIG. 4 illustrates an encapsulation of the semiconductor die, in accordance with some embodiments.

FIG. 5 illustrates a thinning of the semiconductor wafer, in accordance with some embodiments.

FIG. 6 illustrates a formation of a redistribution structure, in accordance with some embodiments.

FIGS. 7-9 illustrate different embodiments of the seal ring, in accordance with some embodiments.

FIG. 10 illustrates a face-to-back configuration, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described with respect to specific embodiments in which devices within a system on integrated circuit (SoIC) utilize seal rings which extend into the respective bonding layers of the individual devices. However, the embodiments illustrated herein are only intended to be illustrative of the embodiments and are not intended to limiting. Rather, the ideas presented herein may be incorporated into a wide variety of embodiments, and all such embodiments are fully intended to be included within the scope of the embodiments.

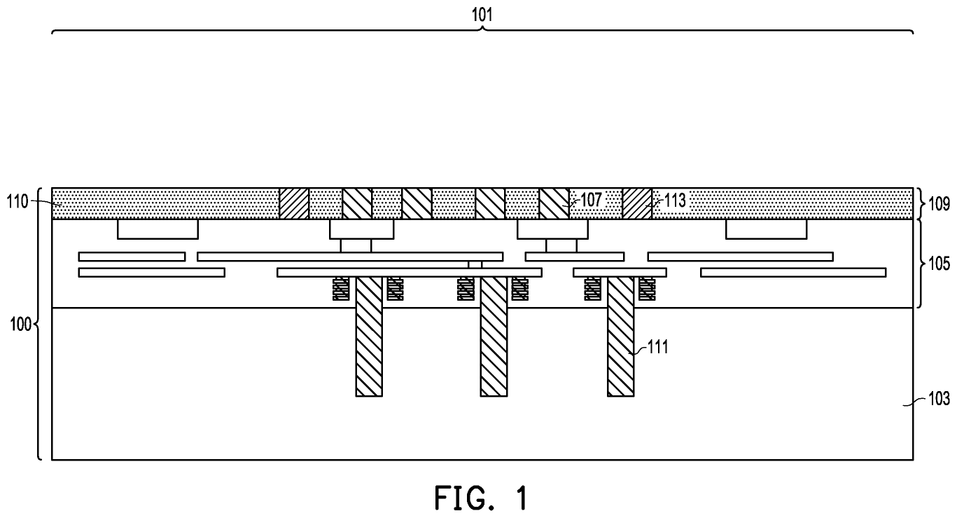

With reference now to FIG. 1, a semiconductor wafer 100 is illustrated with multiple first semiconductor devices 101 (only one of which is illustrated in FIG. 1) formed with and over the semiconductor wafer 100. In a particular embodiment the first semiconductor devices 101 may be a memory device, such as a wide I/O dynamic random access memory (DRAM) device which has a large number of I/O interfaces, such as greater than 256 interfaces. However, the first semiconductor devices 101 may also be any other suitable type of memory device with a high rate of data transfer, such as an LPDDRn memory device or the like, that has a high rate of data transfer, or may be any other suitable device, such as logic dies, central processing unit (CPU) dies, input/output dies, combinations of these, or the like. Additionally, the semiconductor wafer 100 may be received by the manufacturer from a third party manufacturer, or may be manufactured in house.

In an embodiment the first semiconductor devices 101 may comprise a first substrate 103, first active devices (not separately illustrated in FIG. 1), first metallization layers 105, a first bond layer 109, a first dielectric material 110, first bond pads 107, and first bond metal 113. The first substrate 103 may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

The first active devices comprise a wide variety of active devices such as transistors and passive devices such as capacitors, resistors, inductors and the like that may be used to generate the desired structural and functional requirements of the design for the first semiconductor devices 101. The first active devices may be formed using any suitable methods either within or else on the first substrate 103.

The first metallization layers 105 are formed over the first substrate 103 and the first active devices and are designed to connect the various active devices to form functional circuitry. In an embodiment the first metallization layers 105 are formed of alternating layers of dielectric (e.g., low-k dielectric materials, extremely low-k dielectric material, ultra low-k dielectric materials, combinations of these, or the like) and conductive material and may be formed through any suitable process (such as deposition, damascene, dual damascene, etc.). In an embodiment there may be four layers of metallization separated from the first substrate 103 by at least one interlayer dielectric layer (ILD), but the precise number of first metallization layers 105 is dependent upon the design of the first semiconductor devices 101.

Additionally, at any desired point in the manufacturing process, through substrate vias 111 may be formed within the first substrate 103 and, if desired, one or more layers of the first metallization layers 105, in order to provide electrical connectivity from a front side of the first substrate 103 to a back side of the first substrate 103. In an embodiment the TSVs 111 may be formed by initially forming through silicon via (TSV) openings into the first substrate 103 and, if desired, any of the overlying first metallization layers 105 (e.g., after the desired first metallization layer 105 has been formed but prior to formation of the next overlying first metallization layer 105). The TSV openings may be formed by applying and developing a suitable photoresist, and removing portions of the underlying materials that are exposed to a desired depth. The TSV openings may be formed so as to extend into the first substrate 103 to a depth greater than the eventual desired height of the first substrate 103. Accordingly, while the depth is dependent upon the overall designs, the depth may be between about 20 μm and about 200 μm, such as a depth of about 50 μm.

Once the TSV openings have been formed within the first substrate 103 and or any first metallization layers 105, the TSV openings may be lined with a liner. The liner may be, e.g., an oxide formed from tetraethylorthosilicate (TEOS) or silicon nitride, although any suitable dielectric material may be used. The liner may be formed using a plasma enhanced chemical vapor deposition (PECVD) process, although other suitable processes, such as physical vapor deposition or a thermal process, may be used. Additionally, the liner may be formed to a thickness of between about 0.1 μm and about 5 μm, such as about 1 μm.

Once the liner has been formed along the sidewalls and bottom of the TSV openings, a barrier layer may be formed and the remainder of the TSV openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer, filling and overfilling the TSV openings. Once the TSV openings have been filled, excess liner, barrier layer, seed layer, and first conductive material outside of the TSV openings may be removed through a planarization process such as chemical mechanical polishing (CMP), although any suitable removal process may be used.

The first bond layer 109 may be formed on the first substrate 103 over the first metallization layers 105. The first bond layer 109 may be used for dielectric-to-dielectric and metal-to-metal bonding or fusion bonding (also referred to as oxide-to-oxide bonding). In accordance with some embodiments, the first bond layer 109 is formed of the first dielectric material 110 such as silicon oxide, silicon nitride, or the like. The first dielectric material 110 may be deposited using any suitable method, such as, atomic layer deposition (ALD), CVD, high-density plasma chemical vapor deposition (HDPCVD), PVD, or the like to a thickness of between about 1 nm and about 1000 nm, such as about 5 nm. However, any suitable material, process, and thickness may be utilized.

Once the first dielectric material 110 has been formed, bond openings may be formed within the first dielectric material 110 to prepare for the formation of the first bond pads 107 and the first bond metal 113. In an embodiment the bond openings may be formed by first applying and patterning a photoresist over the top surface of the first dielectric material 110. The photoresist is then used to etch the first bond layer 109 in order to form the openings. The first bond layer 109 may be etched by dry etching (e.g., reactive ion etching (RIE) or neutral beam etching (NBE)), wet etching, or the like. In accordance with some embodiments of the present disclosure, the etching stops on the first metallization layers 105 such that the first metallization layers 105 are exposed through the openings in the first bond layer 109.

Once the first metallization layers 105 have been exposed, the first bond pads 107 may be formed in physical and electrical contact with the first metallization layers 105. In an embodiment the first bond pads 107 may comprise a barrier layer, a seed layer, a fill metal, or combinations thereof (not separately illustrated). For example, the barrier layer may be blanket deposited over the first metallization layers 105. The barrier layer may comprise titanium, titanium nitride, tantalum, tantalum nitride, or the like. The seed layer may be a conductive material such as copper and may be blanket deposited over the barrier layer using processes such as sputtering, evaporation, or plasma-enhanced chemical vapor deposition (PECVD), or the like, depending upon the desired materials. The fill metal may be a conductor such as copper or a copper alloy and may be deposited over the seed layer to fill or overfill the openings through a plating process such as electrical or electroless plating. Once the fill metal has been deposited, excess material of the fill metal, the seed layer, and the barrier layer may be removed from outside of the openings through a planarization process such as chemical mechanical polishing. However, while a single damascene process has been described, any suitable method, such as a dual damascene process, may also be utilized.

Additionally, in some embodiments bond pad vias (not separately illustrated in FIG. 1) may also be utilized to connect the first bond pads 107 with underlying conductive portions and, through the underlying conductive portions, connect the first bond pads 107 with the underlying first metallization layers 105. In this embodiment the bond pad vias may be formed prior to or simultaneously with the first bond pads 107, such as by using a damascene or dual damascene process. However, any suitable methods and materials may be utilized.

Finally, within the first bond layer 109, the first bond metal 113 may be manufactured. In an embodiment the first bond metal 113 may be manufactured using similar materials and similar processes as the first bond pads 107 and may be performed either simultaneously or sequentially with the first bond pads 107. During the manufacture of the first bond metal 113, first bond metal vias (not separately illustrated in FIG. 1) may also be formed between the first bond metal 113 and the underlying first metallization layer 105. However, any suitable materials and processes may be utilized.

However, the above described embodiment in which the first bond layer 109 is formed, patterned, and the first bond pads 107 and the first bond metal 113 are plated into openings before being planarized is intended to be illustrative and is not intended to be limiting upon the embodiments. Rather, any suitable method of formation of the first bond layer 109, the first bond pads 107, and the first bond metal 113 may be utilized. In other embodiments, the first bond pads 107 and first bond metal 113 may be formed first using, for example, a photolithographic patterning and plating process, and then dielectric material is used to gap fill the area around the first bond pads 107 and the first bond metal 113 before being planarized using a planarization process. Any such manufacturing process is fully intended to be included within the scope of the embodiments.

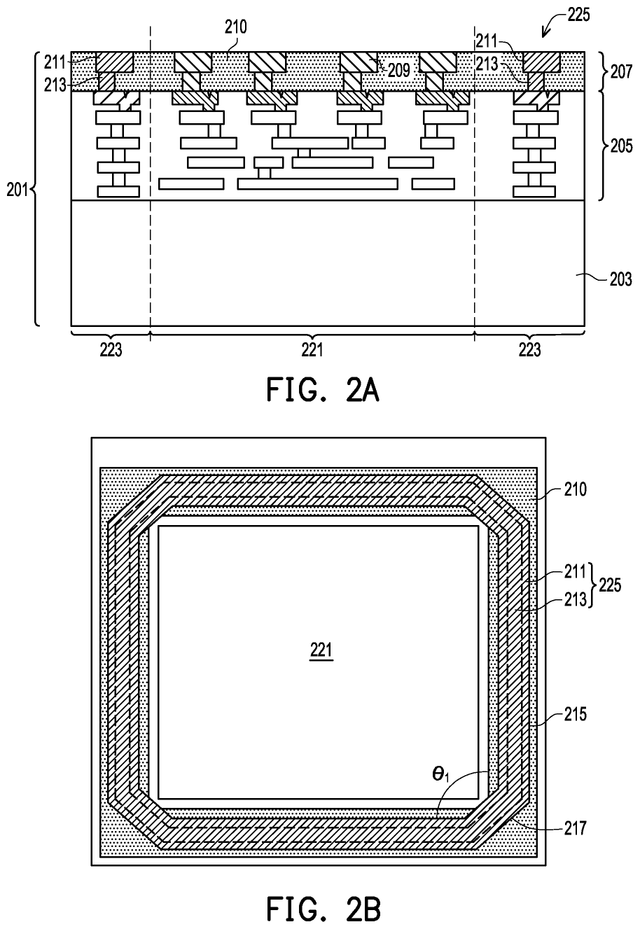

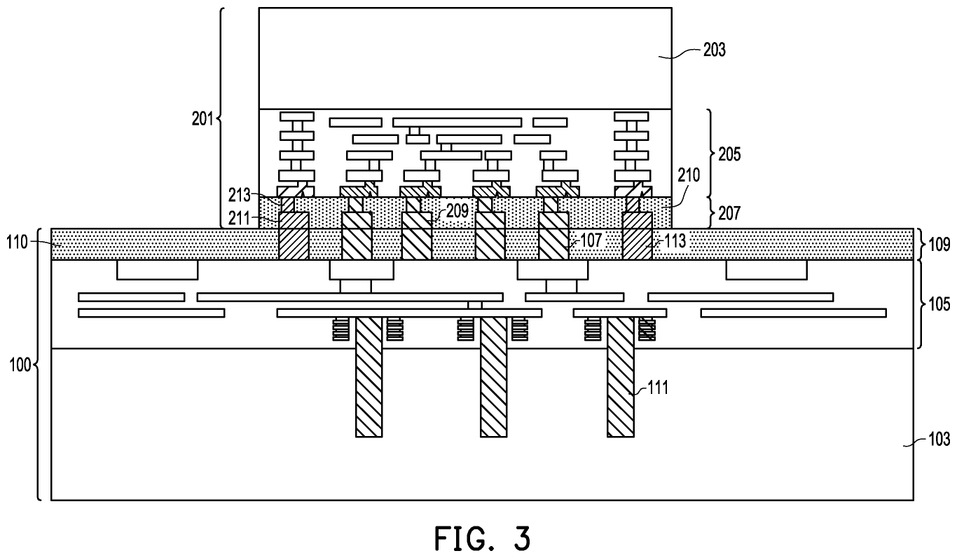

FIG. 2A illustrates a second semiconductor device 201 that will be bonded to the first bond layer 109 (wherein the bonding is not illustrated in FIG. 2 but illustrated and discussed further below with respect to FIG. 3). In an embodiment the second semiconductor device 201 may be a system on chip device, such as a logic device, which is intended to work in conjunction with the first semiconductor devices 101 (e.g., the wide I/O DRAM devices). However, any suitable functionality, such as logic dies, central processing unit (CPU) dies, input/output dies, combinations of these, or the like, may be utilized.

In an embodiment the second semiconductor device 201 may have a second substrate 203, second active devices (not separately illustrated), second metallization layers 205, a second bond layer 207, a second dielectric layer 210, second bond pads 209, a second bond metal 211, and second bond metal vias 213. In an embodiment the second substrate 203, second active devices, second metallization layers 205, second bond layer 207, second bond pads 209, second bond metal 211, and second bond metal vias 213 may be formed similar to the first substrate 103, the first active devices, the first metallization layers 105, the first bond layer 109, the first bond pads 107, the first bond metal 113, and the first bond metal vias, described above with respect to FIG. 1. However, in other embodiments these structures may be formed using different processes and different materials.

FIG. 2A additionally illustrates that, in some embodiments, the second semiconductor device 201 may have a functional region 221 that is surrounded by a closed loop seal ring region 223. In particular, and looking first at the functional region 221, the first active devices, the second metallization layers 205 and the second bond pads 209 are interconnected to provide the desired functions of the second semiconductor device 201 without being reliant upon or even electrically connected with any devices of the second semiconductor device 201 outside of the functional region 221.

The seal ring region 223 is located outside of the functional region 221 and is utilized to place a first seal ring 225 that is located proximate to the edge of the second semiconductor device 201. In some embodiments the first seal ring 225 comprises portions of the second metallization layers 205, the second bond metal vias 213, and the second bond metal 211. Collectively the portions of the second metallization layers 205, the second bond metal vias 213 and the second bond metal 211 located within the seal ring region 223 form a ring (in a top down view) that surrounds the functional region 221 and helps provide protection to the functional region 221 during subsequent processing and operation.

FIG. 2B illustrates one such top down view in which the second bond metal 211 and the second bond metal vias 213 (viewed in FIG. 2B by the dashed lines within the second bond metal 211 because the second bond metal vias 213 are located beneath the second bond metal 211) within the seal ring region 223 surrounds the functional region 221. As can be seen in FIG. 2B, the first seal ring 225 can be formed in some embodiments as an octagonal pattern.

In a particular embodiment the octagonal pattern comprises extended sides 215 and tilted sides 217 connecting the different extended sides 215. In this embodiment the extended sides 215 extend parallel to sides of the functional region 221, while the tilted sides 217 connect the different extended sides 215 and are located adjacent to corners of the functional region 221, where cracks are more likely to occur. In some embodiments the tilted sides 217 may be arranged to have a first angle θ₁ of between about 0° and about 90°, such as about 45°. However, any suitable arrangement may be utilized.

Of course, while the first seal ring 225 may be formed in an octagonal shape in the embodiment illustrated in FIG. 2B, this is intended to be illustrative of the embodiments and is not intended to limit the embodiments to the precise octagonal shape as described above. Rather, the first seal ring 225 may be formed in any suitable shape, such as by having more than a single tilted side arranged at each corner. All such shapes are fully intended to be included within the scope of the embodiments.

FIG. 3 illustrates that, once the second semiconductor device 201 has been prepared, the second semiconductor device 201 is bonded to the first semiconductor devices 101 (still in wafer form) using, for example, dielectric-to-dielectric and metal-to-metal bonding. In an embodiment the surfaces of the first semiconductor devices 101 (e.g., the first dielectric material 110, the first bond pads 107, and the first bond metal 113) and the surfaces of the second semiconductor device 201 (e.g., the second dielectric layer 210, the second bond pads 209, and the second bond metal 211) may initially be activated. Activating the top surfaces of the first semiconductor devices 101 and the second semiconductor device 201 may comprise a dry treatment, a wet treatment, a plasma treatment, exposure to an inert gas plasma, exposure to H₂, exposure to N₂, exposure to O₂, or combinations thereof, as examples. In embodiments where a wet treatment is used, an RCA cleaning may be used, for example. In another embodiment, the activation process may comprise other types of treatments. The activation process assists in the dielectric-to-dielectric and metal-to-metal bonding of the first semiconductor devices 101 and second semiconductor device 201.

After the activation process, the second semiconductor device 201 may be placed into contact with the first semiconductor devices 101. In a particular embodiment in which dielectric-to-dielectric and metal-to-metal bonding is utilized, the first bond pads 107 are placed into physical contact with the second bond pads 209, the first dielectric material 110 is placed into physical contact with the second dielectric layer 210, and the first bond metal 113 is placed into contact with the second bond metal 211. With the activation process chemically modifying the surfaces, the bonding process between the materials is begun upon the physical contact.

Once physical contact has begun the bonding process, the bonding may then be strengthened by subjecting the assembly to a thermal treatment. In an embodiment the first semiconductor devices 101 and the second semiconductor device 201 may be subjected to a temperature between about 200° C. and about 400° C. to strengthen the bond between the first bond layer 109 and the second bond layer 207. The first semiconductor devices 101 and the second semiconductor device 201 may then be subjected to a temperature at or above the eutectic point for material of the first bond pads 107, the second bond pads 209, the first bond metal 113 and the second bond metal 211. In this manner, fusion of the first semiconductor devices 101 and the second semiconductor device 201 forms a hybrid bonded device.

Additionally, while specific processes have been described to initiate and strengthen the dielectric-to-dielectric and metal-to-metal bonding bonds between the first semiconductor devices 101 and the second semiconductor device 201, these descriptions are intended to be illustrative and are not intended to be limiting upon the embodiments. Rather, any suitable combination of baking, annealing, pressing, or other bonding processes or combination of processes may be utilized. All such processes are fully intended to be included within the scope of the embodiments.

Also, while dielectric-to-dielectric and metal-to-metal bonding has been described as one method of bonding the first semiconductor devices 101 to the second semiconductor device 201, this as well is only intended to be illustrative and is not intended to be limiting upon the embodiments. Rather, any suitable method of bonding, such as fusion bonding, copper-to-copper bonding, or the like, may also be utilized. Any suitable method of bonding the first semiconductor devices 101 to the second semiconductor device 201 may be utilized.

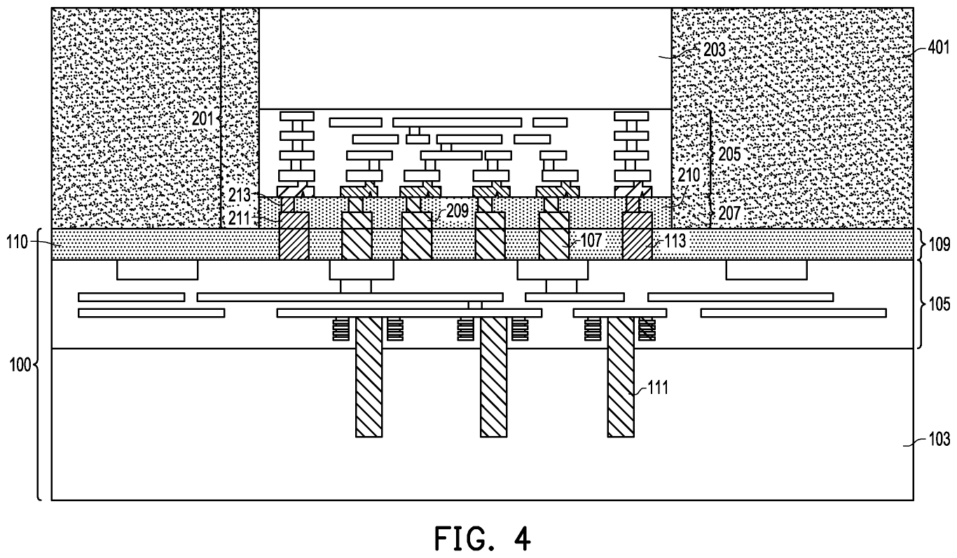

FIG. 4 illustrates that, once the second semiconductor device 201 has been bonded to the first semiconductor devices 101, the second semiconductor device 201 may be encapsulated over the first semiconductor devices 101 with a first encapsulant 401. In an embodiment the encapsulation may be performed in a molding device, which may comprise a top molding portion and a bottom molding portion separable from the top molding portion. When the top molding portion is lowered to be adjacent to the bottom molding portion, a molding cavity may be formed for the first semiconductor devices 101 and the second semiconductor device 201.

During the encapsulation process the top molding portion may be placed adjacent to the bottom molding portion, thereby enclosing the first semiconductor devices 101 and the second semiconductor device 201 within the molding cavity. Once enclosed, the top molding portion and the bottom molding portion may form an airtight seal in order to control the influx and outflux of gasses from the molding cavity. Once sealed, a first encapsulant 401 may be placed within the molding cavity.

The first encapsulant 401 may be an epoxy or a molding compound resin such as polyimide, polyphenylene sulfide (PPS), polyetheretherketone (PEEK), poly ether sulphone (PES), a heat resistant crystal resin, combinations of these, or the like. The first encapsulant 401 may be placed within the molding cavity prior to the alignment of the top molding portion and the bottom molding portion, or else may be injected into the molding cavity through an injection port, using compression molding, transfer molding, or the like.

Once the first encapsulant 401 is placed into the molding cavity such that the first encapsulant 401 encapsulates the second semiconductor device 201, the first encapsulant 401 may be cured in order to harden the first encapsulant 401 for optimum protection. While the exact curing process is dependent at least in part on the particular material chosen for the first encapsulant 401, in an embodiment in which molding compound is chosen as the first encapsulant 401, the curing could occur through a process such as heating the first encapsulant 401 to between about 100° C. and about 200° C., such as about 125° C. for about 60 sec to about 3000 sec, such as about 600 sec. Additionally, initiators and/or catalysts may be included within the first encapsulant 401 to better control the curing process.

However, as one having ordinary skill in the art will recognize, the curing process described above is merely an exemplary process and is not meant to limit the current embodiments. Other curing processes, such as irradiation or even allowing the first encapsulant 401 to harden at ambient temperature, may also be used. Any suitable curing process may be used, and all such processes are fully intended to be included within the scope of the embodiments discussed herein.

FIG. 4 further illustrates a thinning of the first encapsulant 401 in order to expose the second semiconductor device 201 for further processing. The thinning may be performed, e.g., using a mechanical grinding, chemical approaches, or chemical mechanical polishing (CMP) process whereby chemical etchants and abrasives are utilized to react and grind away the first encapsulant 401 so that the second semiconductor device 201 has been exposed. As such, the second semiconductor device 201 may have a planar surface that is also coplanar with the first encapsulant 401. In another embodiment, the grinding may be omitted. For example, if the second semiconductor device 201 are already exposed after encapsulation, or if it is desired that the first encapsulant 401 remain over the second semiconductor device 201, the grinding may be omitted.

Furthermore, while the CMP process described above is presented as one illustrative embodiment, it is not intended to be limiting to the embodiments. Any other suitable removal process may be used to thin the first encapsulant 401. For example, a series of chemical etches may be utilized. This process and any other suitable process may be utilized to planarize the first encapsulant 401, and all such processes are fully intended to be included within the scope of the embodiments.

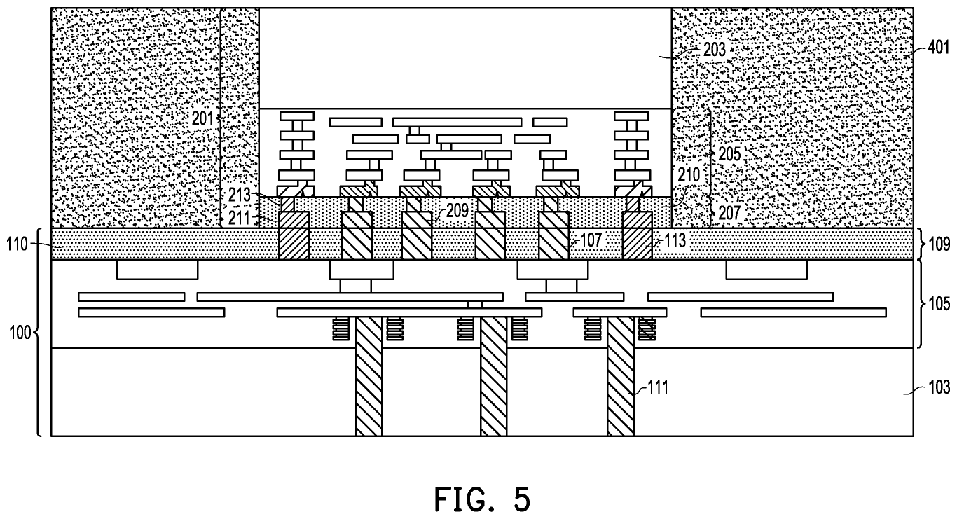

FIG. 5 illustrates a thinning of a back side of the first substrate 103 to expose the TSVs 111. In an embodiment, the thinning of the second side of the first substrate 103 may leave the TSVs 111 exposed. The thinning of the second side of the first substrate 103 may be performed by a planarization process such as CMP or etching. However, any suitable method of thinning the second side of the first substrate 103.

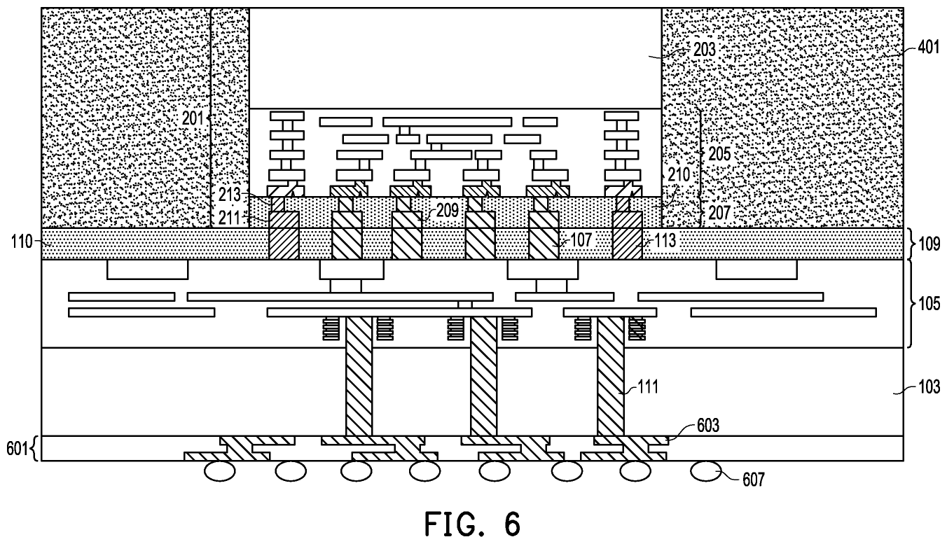

FIG. 6 illustrates a formation of a redistribution structure 601 with one or more layers over the second side of the first substrate 103 and in connection with the TSVs 111. In an embodiment the redistribution structure 601 may be formed by initially forming a first redistribution layer 603 over and in electrical connection with the TSVs 111. In an embodiment the first redistribution layer 603 may be formed by initially forming a seed layer (not shown) of a titanium copper alloy through a suitable formation process such as CVD or sputtering. A photoresist (also not shown) may then be formed to cover the seed layer, and the photoresist may then be patterned to expose those portions of the seed layer that are located where the first redistribution layer 603 is desired to be located.

Once the photoresist has been formed and patterned, a conductive material, such as copper, may be formed on the seed layer through a deposition process such as plating. The conductive material may be formed to have a thickness of between about 1 μm and about 10 μm, such as about 4 μm. However, while the material and methods discussed are suitable to form the conductive material, these materials are merely exemplary. Any other suitable materials, such as AlCu or Au, and any other suitable processes of formation, such as CVD or PVD, may be used to form the first redistribution layer 603.

Once the conductive material has been formed, the photoresist may be removed through a suitable removal process such as chemical stripping and/or ashing. Additionally, after the removal of the photoresist, those portions of the seed layer that were covered by the photoresist may be removed through, for example, a suitable etch process using the conductive material as a mask.

Once the first redistribution layer 603 has been formed, a redistribution passivation layer may be formed. In an embodiment the redistribution passivation layer may be polybenzoxazole (PBO), although any suitable material, such as polyimide or a polyimide derivative, such as a low temperature cured polyimide, may alternatively be utilized. The redistribution passivation layer may be placed using, e.g., a spin-coating process to a thickness of between about 5 μm and about 17 μm, such as about 7 μm, although any suitable method and thickness may be used.

Once the redistribution passivation layer has been formed, the redistribution passivation layer may be patterned to allow for electrical contact to the underlying first redistribution layer 603. In an embodiment the redistribution passivation layer may be patterned using, e.g., a photolithographic masking and etching process. However, any suitable process may be utilized to expose the underlying first redistribution layer 603.

After the redistribution passivation layer has been patterned, if desired, additional layers of the first redistribution layer 603 and the redistribution passivation layer may be formed to provide additional interconnection options. In particular, any suitable number of conductive and dielectric layers may be formed using the processes and materials described herein. All such layers are fully intended to be included within the scope of the embodiments.

Once the redistribution passivation layer has been formed and patterned, first external connectors 607 may be formed. In an embodiment the first external connectors 607 may be, e.g., a ball grid array (BGA) with C4 bumps which comprises a eutectic material such as solder, although any suitable materials may be used. In an embodiment in which the first external connectors 607 are solder bumps, the first external connectors 607 may be formed using a ball drop method, such as a direct ball drop process. In another embodiment, the solder bumps may be formed by initially forming a layer of tin through any suitable method such as evaporation, electroplating, printing, solder transfer, and then performing a reflow in order to shape the material into the desired bump shape. Once the first external connectors 607 have been formed, a test may be performed to ensure that the structure is suitable for further processing.

FIG. 6 additionally illustrates a singulation of the first encapsulant 401 and the first semiconductor devices 101 from a remainder of the semiconductor wafer 100. In an embodiment the singulation may be performed by using a saw blade (not separately illustrated) to slice through the first encapsulant 401 and the semiconductor wafer 100. However, as one of ordinary skill in the art will recognize, utilizing a saw blade for the dicing is merely one illustrative embodiment and is not intended to be limiting. Any method for performing the singulation, such as utilizing one or more etches, may be utilized. These methods and any other suitable methods may be utilized to singulate the structure.

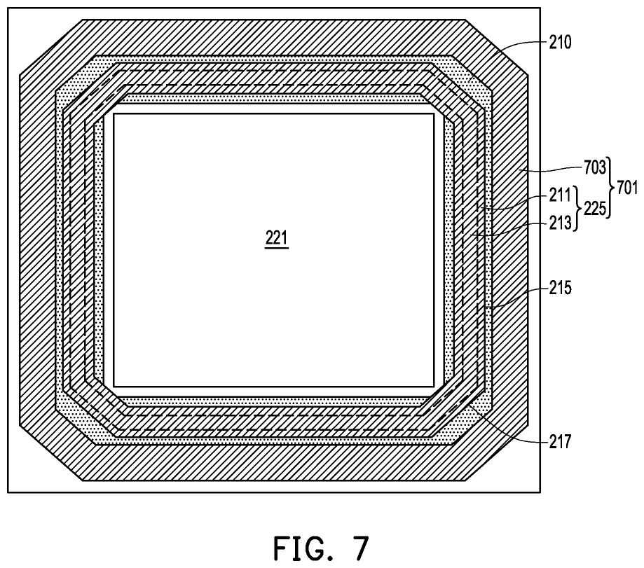

FIG. 7 illustrates a top down view of another embodiment in which a second seal ring 701 comprises both the first seal ring 225 as well as a surrounding outer ring 703. In this embodiment the first seal ring 225 may be formed as described above with respect to FIGS. 2A-2B. However, any suitable methods and materials may be utilized.

With respect to the surrounding outer ring 703, the outer ring 703 may be formed in order to surround the first seal ring 225 and provide even more protection to the functional region 221. In some embodiments the outer ring 703 may be formed using similar materials and methods as the first seal ring 225 and may have an octagonal shape. Additionally, while the outer ring 703 may be formed in multiple levels (similar to the first seal ring 225), in other embodiments the outer ring 703 may be formed at the same level as the second bond metal 211 without additional levels (e.g., without the underlying vias). However, any suitable methods, materials, and shape may be utilized.

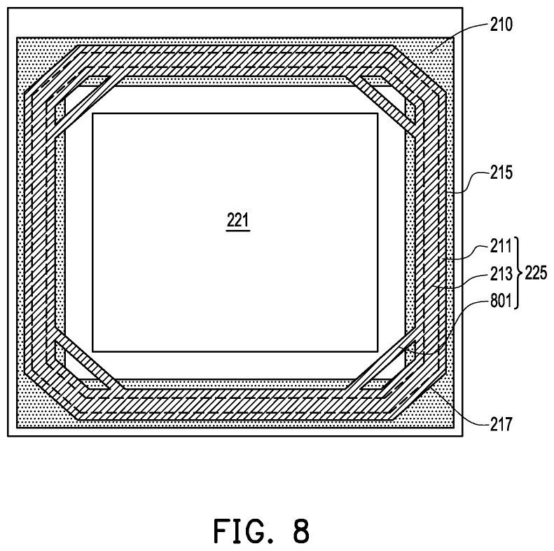

FIG. 8 illustrates a top down view of yet another embodiment in which additional tilted sides 801 are added to the first seal ring 225. In this embodiment the additional tilted sides 801 may be formed at the same level of the remainder of the first seal ring 225 and provide additional protection along the corners of the functional region 221. Additionally, while a single additional tilted side 801 located at each corner is illustrated in FIG. 8, any suitable number, such as 2, 3, or 4 may be formed adjacent to each corner, and any suitable number may be utilized.

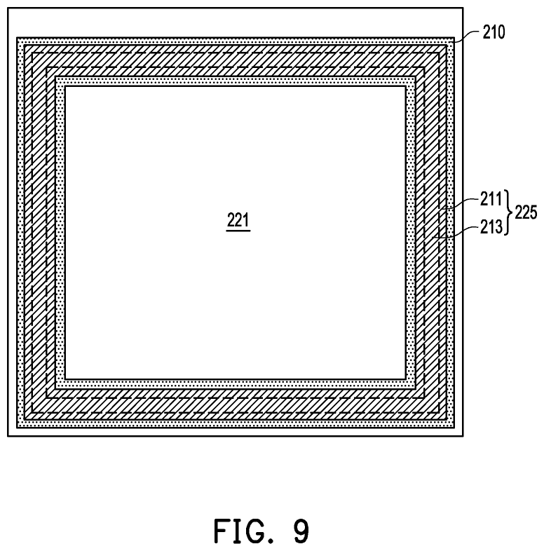

FIG. 9 illustrates a top down view of yet another embodiment in which the first seal ring 225, instead of being in the shape of an octagon (as described above with respect to FIGS. 1-8), is instead in the shape of a square or rectangle. In this embodiment there are no angled sides located at the corners of the functional region 221, and there are a total of four sides to the first seal ring 225. However, any suitable number of sides and any suitable shape may be utilized.

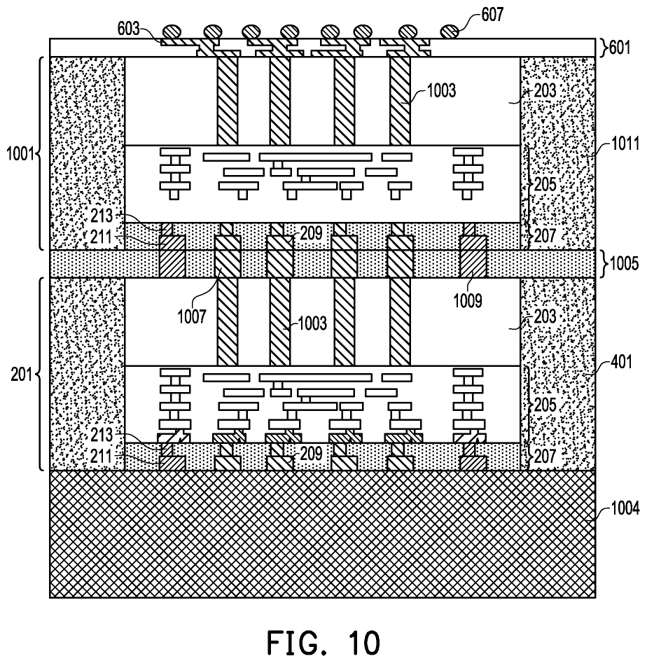

FIG. 10 illustrates yet another embodiment in which the second semiconductor device 201 is bonded to a third semiconductor device 1001 in, e.g., a face-to-back configuration. In this embodiment the second semiconductor device 201 may be formed as described above with respect to FIG. 2, but may further comprise second TSVs 1003 extending through the second substrate 203. In some embodiments the second TSVs 1003 may be formed using similar methods and materials as the first TSVs 111 (described above with respect to FIGS. 1 and 5). However, any suitable methods and materials may be utilized.

Once the second semiconductor device 201 has been prepared, the second semiconductor device 201 may be attached to a carrier wafer 1004 and the first encapsulant 401 may be used to encapsulate the second semiconductor device 201. In an embodiment the second semiconductor device 201 may be attached using either an adhesive layer (not separately illustrated in FIG. 10) or else may be bonded to the carrier wafer 1004. Additionally, the second semiconductor device 201 may be encapsulated with the first encapsulant 401 as described above with respect to FIG. 4 (placing the first encapsulant 401 and then planarizing the first encapsulant 401 until the second through vias 1003 are exposed or re-exposed). However, any suitable methods and materials may be utilized.

Once the second semiconductor device 201 has been attached and encapsulated, a third bond layer 1005 may be formed over the second semiconductor device 201 and the first encapsulant 401. In an embodiment the third bond layer 1005 may comprise fifth bond pads 1007 and a third bond metal 1009, which may be made using similar processes and materials as the first bond layer 109, the first bond pads 107 and the first bond metal 113, described above with respect to FIG. 1. However, any suitable materials and methods may be utilized.

Once the third bond layer 1005 has been formed, the third semiconductor device 1001 may be bonded to the third bond layer 1005. In an embodiment the third semiconductor device 1001 may have similar structures as the second semiconductor device 201, but may or may not have a different design in order to provide a functionality that works in conjunction with the second semiconductor device 201. As such, the third semiconductor device 1001 may have the second substrate 203, the second metallization layers 205, the second bond layer 207, and the second TSVs 1003. Additionally, the third semiconductor device 1001 may be bonded to the third bond layer 1005 using, e.g., a dielectric-to-dielectric and metal-to-metal bonding process, as described above with respect to FIG. 3. However, any suitable devices, structures and methods may be utilized.

Once the third semiconductor device 1001 has been bonded to the third bond layer 1005, the third semiconductor device 1001 may be encapsulated with a second encapsulant 1011. In an embodiment the third semiconductor device 1001 may be encapsulated as discussed above with respect to FIG. 4. However, any suitable methods and materials may be used.

Once the second encapsulant 1011 has been placed and planarized, the redistribution structure 601 may be formed in electrical contact with the second TSVs 1003 in the third semiconductor device 1001. In an embodiment the redistribution structure 601 and the first external connectors 607 may be formed as described above with respect to FIG. 6. However, any suitable methods and materials may be utilized.

By forming the first seal ring 225 to include the second bond metal 211 and the second bond metal vias 213, the first seal ring 225 can connect to the first bond metal 113, forming a continuous, closed loop ring of material that extends from the second semiconductor device 201 to the semiconductor wafer 100. As such, a closed loop is formed which helps to prevent the bonding interface from delaminating and prevent any cracks (from, e.g., thermal mismatch stresses) that do form from extending into the functional region 221. Such protection also helps provide robust metal-to-metal (e.g., Cu-to-Cu) bonds. Such improvements can be formed simultaneously with the other portions of the bond layers and, as such, no additional process steps are involved.

In accordance with an embodiment, a method of manufacturing a semiconductor device, the method including: receiving a first semiconductor device, the first semiconductor device including: a functional region; and a seal ring region, the seal ring region comprising a first seal ring; bonding the first semiconductor device to a semiconductor wafer, the bonding including: bonding a first dielectric of the first semiconductor device to a second dielectric of the semiconductor wafer; bonding first bond pads within the functional region to second bond pads within the semiconductor wafer; and bonding the first seal ring to a first bond metal within the semiconductor wafer. In an embodiment the first seal ring fully surrounds the functional region. In an embodiment the first seal ring has an octagonal shape. In an embodiment the octagonal shape comprises a first tilted side located along a corner of the functional region. In an embodiment the octagonal shape comprises a second tilted side located along the corner of the functional region. In an embodiment the first seal ring has a second octagonal shape surrounding the octagonal shape. In an embodiment the first seal ring has a square shape.

In accordance with another embodiment, a method of manufacturing a semiconductor device, the method including: receiving a semiconductor substrate, the semiconductor substrate comprising a functional region and a seal ring region; manufacturing a first metallization layer, the first metallization layer comprising a first portion within the functional region and a second portion within the seal ring region, the first portion being separated from the second portion; forming a first bond layer, the forming the first bond layer including: forming first bond pads within the functional region; and forming a first bond metal within the seal ring region, the first bond metal and the second portion of the first metallization layer forming a first seal ring; and bonding the first bond metal to a second bond metal within a semiconductor wafer. In an embodiment the forming the first bond layer further comprises forming first bond vias. In an embodiment the first bond metal has a first configuration and the second bond metal has the first configuration. In an embodiment the method further includes encapsulating the semiconductor substrate with an encapsulant. In an embodiment the method further includes thinning the semiconductor wafer to expose through vias after the bonding. In an embodiment the method further includes forming a first redistribution structure in electrical connection with the through vias. In an embodiment the forming the first bond metal forms the first bond metal in an octagonal shape.

In yet another embodiment, a semiconductor device includes: a first semiconductor die, the first semiconductor die including: active devices within a functional region of the first semiconductor die; a first metallization layer, the first metallization layer including: a first portion electrically connected to the active devices; and a second portion forming a first part of a seal ring surrounding the functional region; a first bond layer, the first bond layer including: first bond pads electrically connected to the first portion of the first metallization layer; a first bond metal forming a second part of the seal ring surrounding the functional region; and a second semiconductor die, the second semiconductor die including: second bond pads bonded to the first bond pads; and a second bond metal bonded to the seal ring. In an embodiment the first bond metal has an octagonal shape. In an embodiment the semiconductor device further includes a third bond metal surrounding the seal ring. In an embodiment the first bond metal has multiple tilted sidewalls adjacent to a corner of the functional region. In an embodiment the semiconductor device further includes it surrounding the first semiconductor die and over the second semiconductor die. In an embodiment the first semiconductor die and the second semiconductor die are in a semiconductor on integrated circuit configuration.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
receiving a first semiconductor device, the first semiconductor device comprising:
a functional region; and
a seal ring region, the seal ring region comprising a first seal ring;
bonding the first semiconductor device to a semiconductor wafer, the bonding comprising:
bonding a first dielectric of the first semiconductor device to a second dielectric of the semiconductor wafer;
bonding first bond pads within the functional region to second bond pads within the semiconductor wafer; and
bonding the first seal ring to a first bond metal within the semiconductor wafer.

2. The method of claim 1, wherein the first seal ring fully surrounds the functional region.

3. The method of claim 1, wherein the first seal ring has an octagonal shape.

4. The method of claim 3, wherein the octagonal shape comprises a first tilted side located along a corner of the functional region.

5. The method of claim 4, wherein the octagonal shape comprises a second tilted side located along the corner of the functional region.

6. The method of claim 3, wherein the first seal ring has a second octagonal shape surrounding the octagonal shape.

7. The method of claim 1, wherein the first seal ring has a square shape.

8. A method of manufacturing a semiconductor device, the method comprising:
receiving a semiconductor substrate, the semiconductor substrate comprising a functional region and a seal ring region;
manufacturing a first metallization layer, the first metallization layer comprising a first portion within the functional region and a second portion within the seal ring region, the first portion being separated from the second portion;
forming a first bond layer, the forming the first bond layer comprising:
forming first bond pads within the functional region; and
forming a first bond metal within the seal ring region, the first bond metal and the second portion of the first metallization layer forming a first seal ring; and
bonding the first bond metal to a second bond metal within a semiconductor wafer.

9. The method of claim 8, wherein the forming the first bond layer further comprises forming first bond vias.

10. The method of claim 8, wherein the first bond metal has a first configuration and the second bond metal has the first configuration.

11. The method of claim 8, further comprising encapsulating the semiconductor substrate with an encapsulant.

12. The method of claim 11, further comprising thinning the semiconductor wafer to expose through vias after the bonding.

13. The method of claim 12, further comprising forming a first redistribution structure in electrical connection with the through vias.

14. The method of claim 8, wherein the forming the first bond metal forms the first bond metal in an octagonal shape.

15. A semiconductor device comprising:
a first semiconductor die, the first semiconductor die comprising:
active devices within a functional region of the first semiconductor die;
a first metallization layer, the first metallization layer comprising:
a first portion electrically connected to the active devices; and
a second portion forming a first part of a seal ring surrounding the functional region;
a first bond layer, the first bond layer comprising:
first bond pads electrically connected to the first portion of the first metallization layer;
a first bond metal forming a second part of the seal ring surrounding the functional region; and
a second semiconductor die, the second semiconductor die comprising:
second bond pads bonded to the first bond pads; and
a second bond metal bonded to the seal ring.

16. The semiconductor device of claim 15, wherein the first bond metal has an octagonal shape.

17. The semiconductor device of claim 15, further comprising a third bond metal surrounding the seal ring.

18. The semiconductor device of claim 15, wherein the first bond metal has multiple tilted sidewalls adjacent to a corner of the functional region.

19. The semiconductor device of claim 15, further comprising an encapsulant surrounding the first semiconductor die and over the second semiconductor die.

20. The semiconductor device of claim 15, wherein the first semiconductor die and the second semiconductor die are in a semiconductor on integrated circuit configuration.
